(19) United States
(12) Patent Application Publication
(10) Pub. No.: US 2004/0201049 A1
(43) Pub. Date: Oct. 14, 2004

(54) Suppression of electrode re-crystallisation in a ferrocapacitor

(76) Inventors: Stefan Gernhardt, Kanagawa-ken (JP); Jingyu Lian, Tokyo-to (JP); Rainer Bruchhaus, Kanagawa-ken (JP); Andreas Hilliger, Kanagawa-ken (JP); Nicolas Nagel, Kanagawa-ken (JP); Uwe Wellhausen, Dresden (DE)

Correspondence Address: FISH & RICHARDSON, PC, 12390 EL CAMINO REAL, SAN DIEGO, CA, 92130-2081, US

(21) Appl. No.: 10/413,465

(22) Filed: Apr. 11, 2003

(51) Int. Cl. H01L 21/00

(52) U.S. Cl. 257/295; 438/3

(57) ABSTRACT

An electrode 1 of a ferrocapacitor formed by an etching process is treated by oxygen implantation to reduce the size of crystal domains 15 in side regions 11 of the electrode 1. Subsequently a cover layer 3 is deposited over the side wall of the electrode to protect the ferrocapacitor in subsequent process steps. Later in the fabrication process the ferrocapacitor is subject to heat treatments, but due to the reduced size of the crystal domains 15 the growth of the crystal domains in the side regions 11 of the electrode is more homogenous, and causes reduced stresses in the cover layer 3, leading to a reduced risk of the cover layer 3 failing to protect the ferrocapacitor.

### FIELD OF THE INVENTION

The present invention relates to fabrication processes for ferroelectric devices which include one or more ferrocapacitors, and to ferroelectric devices produced by the fabrication processes.

### BACKGROUND OF INVENTION

It is known to produce ferroelectric devices such as FeRAM devices and high k DRAM devices including ferroelectric capacitors produced by depositing the following layers onto a substructure: a bottom electrode layer, a ferroelectric layer, and a top electrode layer. Hardmask elements, typically formed Tetraethyl Orthosilicate (TEOS), are deposited over the top electrode layer, and used to etch the structure so as to remove portions of the bottom electrode layer, ferroelectric layer, and top electrode layer which are not under the hardmask elements. The etching separates the top electrode layer Into top electrodes, the bottom electrode layer into bottom electrodes, and the ferroelectric layer into ferroelectric elements sandwiched by respective pairs of top electrodes and bottom electrodes. Subsequently, an insulating material such as TEOS is deposited over the completed ferrocapacitors. By repeating the above steps a multi-layer structure can be formed, comprising ferrocapacitors at each of a number of levels of the structure.

During the fabrication process of each ferrocapacitor, the ferroelectric material is generally subject to a crystallization step which is typically performed at temperatures of about 600° C. in an oxygen ambient atmosphere.

To reduce damage to the ferrocapacitor during subsequent process steps (such as the fabrication of higher layers of the device, and/or electrical connections through the device), the ferrocapacitor is encapsulated under a hydrogen diffusion.

The structure of part of the ferrocapacitor is shown schematically in FIG. 1(a) in cross-section. A side portion of a layer 1 of a conductive layer material is shown. This layer 1 is either the top electrode or the bottom electrode of the ferrocapacitor. It carries on its side walls a cover layer 3. The layer 1 as indicated includes multiple crystal domains 5, separated by domain boundaries 6, 7, 8.

During a subsequent heat treatment step (which may be the crystallisation of the ferroelectric layer of the ferrocapacitor of which the electrode 1 is a part, or may be any thermal post-treatment after the capacitor has been finished), the crystal domains 5 tend to grow (“recrystallisation”). This is shown in FIG. 1(b), in which the former position of a domain boundary is shown dashed and again marked as 7. The former position of the cover layer is shown dashed and marked as 3, and the new position of the cover marked as 13. The crystals 5 have grown in a manner dependent on the starting conditions, such as the initial size of the crystals 5 and their locations (called the “texture” of the region 11), stress, temperature and time. In FIG. 1(b), it can easily be seen that the cover layer 13 is stretched by the recrystallisation. If this stretching becomes too great (due to the unfortunate characteristics of the Initial texture of the electrode 1 of a certain ferrocapacitor), the cover layer 13 will suffer damage, reducing its capacity to protect the layer 1 in subsequent processing steps. For example, the cover layer 13 may tear, allowing hydrogen to diffuse into the layer 1. In the worst case this can lead to failure of the ferrocapacitor, a problem known as “single cell fail”.

### SUMMARY OF THE INVENTION

The present invention aims to address the above problem, and to provide a new and useful technique for ferrocapacitor fabrication.

In general terms, the invention proposes that in the fabrication process of a ferrocapacitor, prior to the deposit of a cover layer over a side wall of an electrode layer of the ferrocapacitor, a step should be performed of reducing the size of crystal domains in a side portion of the electrode layer.

The method has the advantage that, due to the reduced size of the crystal domains, the growth of the side regions of the electrode is more homogenous, and causes reduced stresses in the cover layer, leading to a reduced risk of the cover layer failing to protect the ferrocapacitor. In particular, there is a reduced chance that the cover layer will be damaged due to an unfortunate Initial texture of the electrode, leading to a reduced risk of the ferrocapacitor failing.

The step of reducing the crystal domains may for example be performed by oxygen implantation on the sidewalls of the electrode. The oxygen atoms have no harmful effect on the electrode layer (although if desired it would be possible to remove the oxygen atoms by an annealing step). Note that in some embodiments nitrogen or Argon molecules may be used in place of oxygen molecules.

The “size” of the crystal domains may be defined as their mean maximum dimension, or by any other appropriate measure.

### BRIEF DESCRIPTION OF THE FIGURES

Preferred features of the invention will now be described, for the sake of illustration only, with reference to the following figures in which:

FIG. 1, which is composed of FIG. 1(a) and 1(b), shows a process observed during a conventional ferrocapacitor fabrication process; and

FIG. 2, which is composed of FIGS. 2(a) to 2(d), shows process steps of an embodiment of the present Invention.

### DETAILED DESCRIPTION OF THE EMBODIMENTS

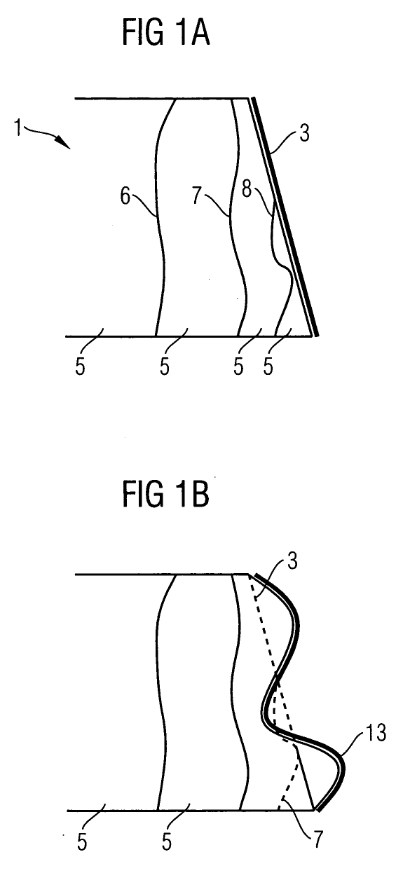

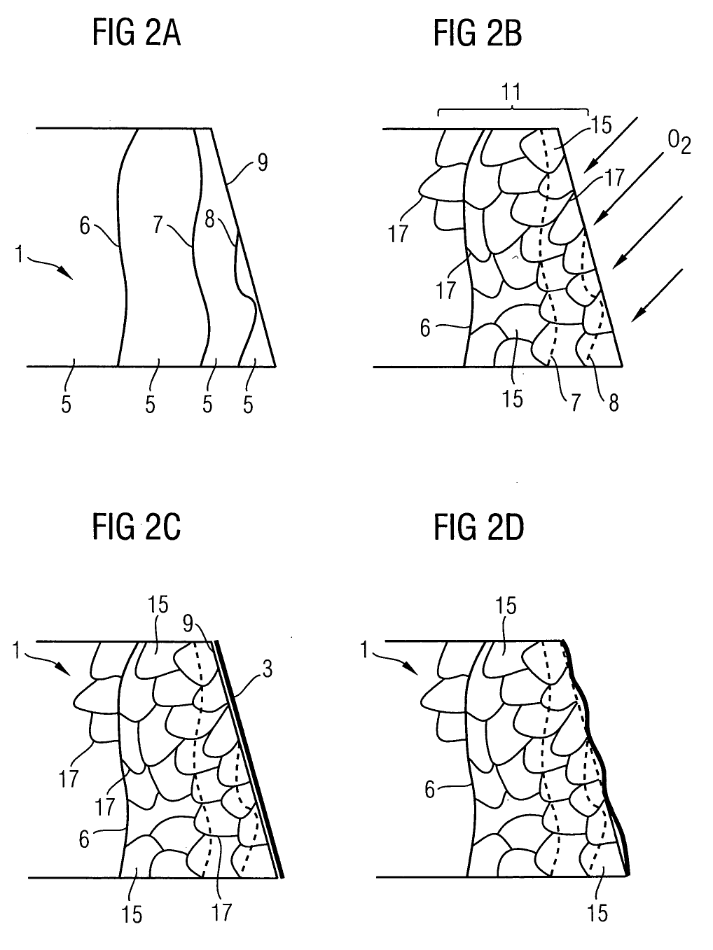

A method which is an embodiment of the invention will now be explained with reference to FIGS. 2(a) to 2(c). The reference numerals employed in FIGS. 1(a) and 1(b) are used in FIGS. 2(a) to 2(d) to Indicate items having equivalent meaning.

Referring firstly to FIG. 2(a), the structure of an electrode 1 (which may be either of the top electrode element or bottom electrode of a ferrocapacitor) is shown following the conventional etching step in which the electrode is formed, and prior to the deposit of a cover layer on the side wall 9 of the electrode. As in FIG. 1(a), the electrode 1 includes crystal domains 5 having crystal boundaries, such as boundaries 6, 7, 8.

As shown in FIG. 2(b), an oxygen implantation step is performed in which the side wall 9 is bombarded with oxygen molecules. To accelerate the O₂ molecules they have to be ionized (which is performed in the implanter). After the ions arrive at their target they are mostly neutralised. Note that in some embodiments N₂ or Ar may be used In place of O₂ molecules.

As indicated in the figure the domains 5 in a side region 11 of the electrode 1 are reduced in size in this operation. Whereas the Initial width of the electrode domains is more than 10 nm, and a typical width of 20-50 nm, the embodiment aims to make the maximum width of the particles less than 5 nm, and the average width about 2 nm. The previous positions of the domain boundaries 7, 8 of FIG. 2(a), are shown as dashed lines In FIG. 2(b), again marked as 7, 8. The domain boundaries of the newly created domains 15 are shown as 17. The crystal boundary 6 of FIG. 2(a) still remains in the structure of FIG. 2(b) since it is at the edge of the side region 11 of the electrode 1.

The further steps of the fabrication method are as in conventional methods. Specifically, in the next process step, as shown in FIG. 2(c), a cover layer 3 is deposited over the side wall 9 of the electrode 1, by the conventional technique. Later in the fabrication process the structure will be subject to heat treatment steps (which may be the crystallisation of the ferroelectric layer of the ferrocapacitor of which the layer 1 is a part, or may be the crystallisation of a ferroelectric layer of a ferrocapacitor higher in the structure), but during these steps the portion of the structure shown in FIG. 2(c) is changed into the structure shown in FIG. 2(d). Due to the reduced size of the crystals 15, and their homogenous distribution, the effects of the initial texture of the electrode 1 are suppressed, and the process window is widened dramatically.

Although the invention has been described above in relation to a single embodiment, many variations are possible within the scope of the invention as will be clear to a skilled reader. For example, instead of oxygen implantation, other chemical treatment processes may be employed to reduce the crystal domain size of the domains in the side region 11 proximate the side wall 9.

Note that the problem of uneven domain growth in electrodes which is addressed by the embodiment, does not occur in the ferroelectric layer, and therefore no treatment step is necessary there. In practice, in the embodiment the ferroelectric layer will experience the oxygen implantation also, but this does not create a problem. If in other embodiments oxygen implantation into the ferroelectric (or other) layer did have some undesired effect, it would be straightforward to protect the ferroelectric (or other) layers from the oxygen Implantation using a masking material, such as TEOS.

1. A method of fabricating a ferrocapacitor device, the method including:
forming a ferrocapacitor structure comprising an upper electrode and a lower electrode sandwiching a ferroelectric element;
reducing the size of crystal domains to less than 5 nm in a side portion of at least one of the upper electrode and lower electrode; and
depositing a cover layer over the side wall of the electrode.

2. A method according to claim 1 in which the size of the crystal domains is reduced by oxygen implantation.

3. (canceled)

4. A method according to claim 1 in which the size of the crystal domains is reduced such that their average domains is about 2 nm.

5. A method according to claim 1 in which the size of the crystal domains is reduced in both the top and bottom electrode.

6. A ferrocapacitor device formed by a fabrication process forming a ferrocapacitor structure comprising an upper electrode and a lower electrode sandwiching a ferroelectric element;
reducing the size of crystal domains to less than 5 nm in a side portion of at least one of the upper electrode and lower electrode; and
depositing a cover layer over the side wall of the electrode.

7. A device according to claim 6 which is an FeRAM memory device.

8. A method according to claim 1 in which the size of the crystal domains is reduced by oxygen implantation after sandwiching the ferroelectric element between the upper electrode and the lower electrode.
